(19) United States
(12) Patent Application Publication
(10) Pub. No.: US 2002/0037617 A1
(43) Pub. Date: Mar. 28, 2002

(54) Method for forming gate electrodes in a semicoductor device using formed fine patterns

(76) Inventors: Jun Dong Kim, Seoul (KR); Bum Jin Jun, Kyoungki-do (KR)

Correspondence Address: Finnegan, Henderson, Farabow,, Garrett & Dunner, L.L.P., 1300 I Street, N.W., Washington, DC, 20005-3315, US

(21) Appl. No.: 09/892,878

(22) Filed: Jun. 28, 2001

(30) Foreign Application Priority Data
Jun. 29, 2000 (KR) 2000-36495

(51) Int. Cl. H01L 21/336

(52) U.S. Cl. 438/270

(57) ABSTRACT

A method for forming fine patterns and a using the method for forming gate electrodes of a semiconductor device are provided. The gate electrodes are formed by: forming a gate insulation layer over a semiconductor wafer; forming a conductive layer for the gate electrodes over the gate insulation layer; forming a low-dielectric layer over the conductive layer for the gate electrodes; forming a photoresist pattern whose width is equal to the exposure limit on the low-dielectric layer; patterning the low-dielectric layer using the photoresist pattern as a mask; removing the photoresist pattem; shrinking the low-dielectric pattern; and patterning the conductive layer for gate electrodes and the gate insulation layer using the shrunken low-dielectric pattern as a mask, thereby forming the gate electrodes.

### BACKGROUND OF THE INVENTION

1. Field of the Invention

The present invention relates to a method for forming fine patterns of a semiconductor device, and using the method for forming gate electrodes, and more particularly, to a method for forming gate electrodes using a method for forming fine patterns of a semiconductor device with features less than 0.1 μm.

2. Background of the Invention

FIGS. 1A and 1B are sectional views illustrating a conventional method for forming gate electrodes of a semiconductor device. Referring to FIG. 1A, a gate insulation layer 12, a conductive layer 13 such as a doped polysilicon layer, and a hard mask layer 14 are deposited over a semiconductor wafer 11 in sequence. The hard mask layer 14 prevents irregular reflection during patterning of the conductive layer 13 to form gate electrodes. The hard mask layer 14 is formed of a silicon oxide layer or silicon nitride layer and may act as insulation layer for a self-aligned contact. A photoresist pattern 15 is then formed on the hard mask layer 14 by a known photolithography process. The minimum width “W” of the photoresist pattern 15, which can be patterned by an existing exposure system, is limited to 0.12-0.13 μm.

Referring to FIG. 1B, the hard mask layer 14 is patterned using the photoresist pattern 15 as a mask, and the used photoresist pattern 15 is then stripped. Next, the conductive layer 13 and the gate insulation layer 12 are patterned in sequence using the hard mask pattern 14 as a mask, thereby completing a gate electrode “g.”

As the integration density of semiconductor devices increases, the feature size becomes smaller. In particular, future generation devices, such as 1 gigabytes or greater DRAMs, need gate electrodes with a feature size less than 0.10 μm. However, existing exposure systems can not achieve a feature size less than 0.10 μm. Accordingly, there is a need for a new high-performance exposure system. Use of electron beams as an exposure light source has been considered, however, the time to process gate electrodes increases when such exposure light sources are used, resulting in a reduced yield.

### SUMMARY OF THE INVENTION

To solve the problems associated with the conventional methods of forming gate electrodes, it is an object of the present invention to provide a method for forming fine patterns of a semiconductor device having a feature size less than 0.1 μm using an existing exposure system.

It is another object of the present invention to provide a method for forming a gate electrode with a feature size less than 0.1 μm using an existing exposure system.

In an aspect of the present invention, there is provided a method for forming gate electrodes of a semiconductor device, the method comprising: forming a gate insulation layer over a semiconductor wafer; forming a conductive layer for the gate electrodes over the gate insulation layer; forming a low-dielectric layer over the conductive layer for the gate electrodes; forming a photoresist pattern whose width is equal to the exposure limit on the low-dielectric layer; patterning the low-dielectric layer using the photoresist pattern as a mask; removing the photoresist pattern; shrinking the low-dielectric pattern; and patterning the conductive layer for gate electrodes and the gate insulation layer using the shrunken low-dielectric pattern as a mask, thereby forming the gate electrodes.

In another aspect of the present invention, there is provided a method for forming fine patterns of a semiconductor device, the method comprising: forming a material layer for the fine patterns over a semiconductor wafer; forming a low-dielectric layer over the material layer for the fine patterns; forming a photoresist pattern whose width is equal to the exposure limit on the low-dielectric layer; patterning the low-dielectric layer using the photoresist pattern as a mask; removing the photoresist pattern; shrinking the low-dielectric pattern; and patterning the material layer for the fine patterns using the shrunken low-dielectric pattern as a mask, thereby forming the fine patterns.

### BRIEF DESCRIPTION OF THE DRAWINGS

The above objects and advantages of the present invention will become more apparent by describing in detail preferred embodiments thereof with reference to the attached drawings in which:

FIGS. 1A and 1B are sectional views illustrating a conventional method for forming a gate electrode of a semiconductor device; and

FIGS. 2A, 2B, 2C, 2D and 2E are sectional views illustrating a method for forming a gate electrode of a semiconductor device according to the present invention.

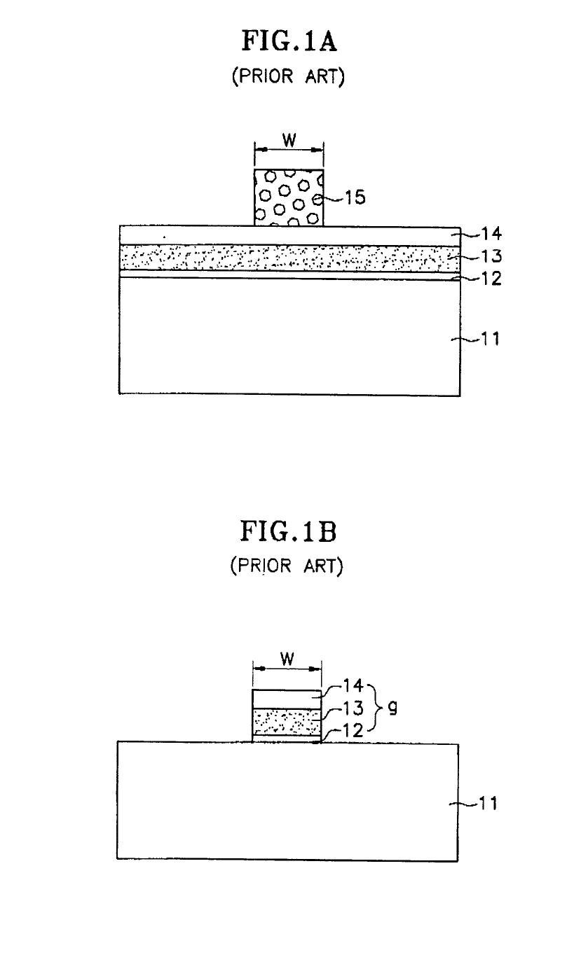

### DESCRIPTION OF THE EMBODIMENTS

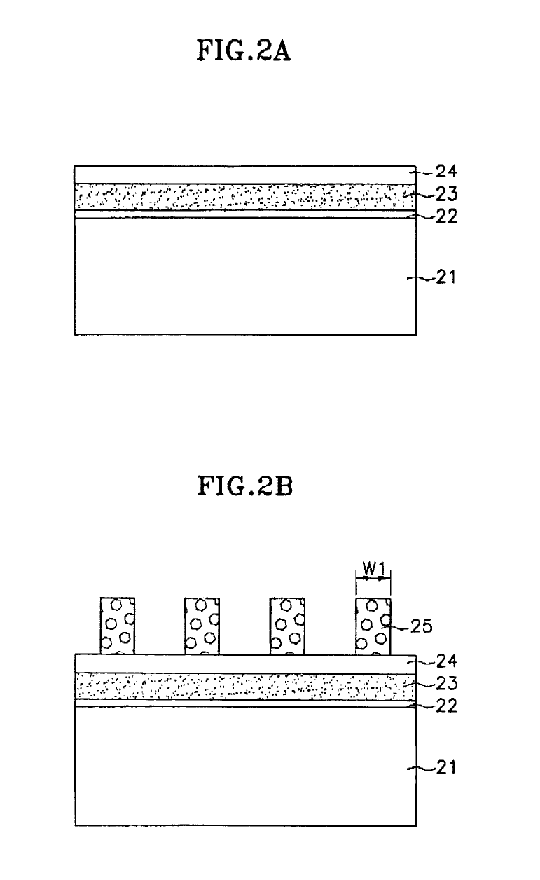

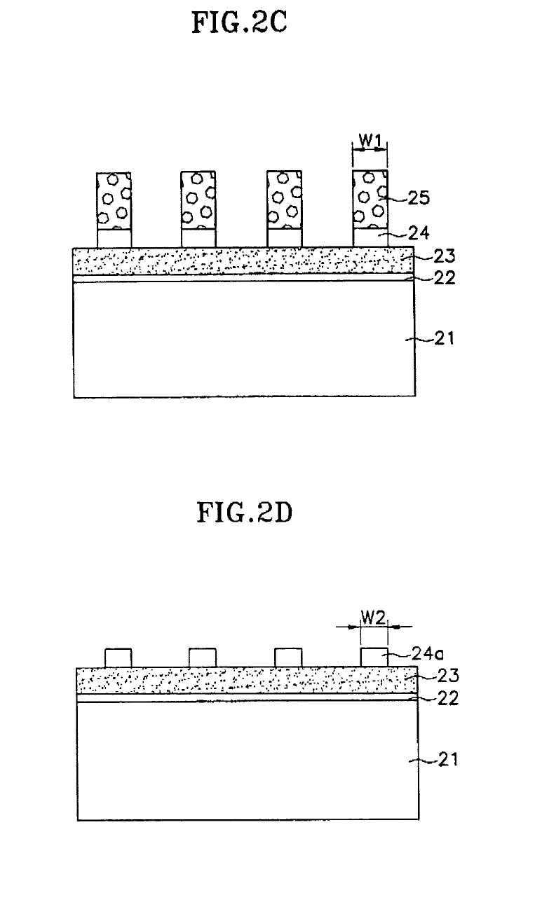

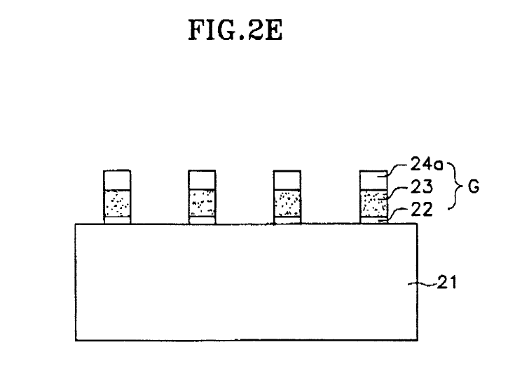

The present invention will now be described more fully with reference to FIGS. 2A through 2E, in which preferred embodiments of the invention are shown.

Referring to FIG. 2A, a gate insulation layer 22, a conductive layer 23 for gate electrodes, and a low-dielectric layer 24 as a hard mask layer are deposited over a semiconductor wafer 21 in sequence. The conductive layer 23 for gate electrodes may be formed of a doped polysilicon layer, refractory silicide layer, or refractory metal layer. The width and depth of the low-dielectric layer 24 is shrinkable during a thermal process performing the deposition. The low-dielectric layer 24 may be formed of an organic or inorganic spin-on-glass (SOG) layer. Table 1 shows the shrinkage ratios of organic or inorganic SOG layers during a curing process. As shown in Table 1, the organic or inorganic SOG layers shrink by about 10% when cured at a predetermined temperature.

TABLE 1
Shrinkage Ratios of SOG Layers

| Types of low- | Shrinkage ratio | | |
|---|---|---|---|
| dielectric layer | (%) | Temperature (° C.) | Time |
| Silicate (Inorganic | 12-14 | 425, 900 | 1 hr |
| SOG) | | | |
| Phosphosilicate | 16-18 | 425 | 1 hr |
| (Inorganic SOG) | | | |
| Siloxanis | 2-13 | 425 | 1 hr |
| (Organic SOG) | | | |
| Silicesquinoxanis | 12 | 400 | 30 min |
| (Organic SOG) | | | |
| Hydrogen silicate | 8 | 400 | 30 min |
| (Inorganic SOG) | | | |
| Hydrogen | Less than 4 | 400 | 30-60 min |
| silicesquinoxane | | | |
| (Inorganic SOG) | | | |

After the deposition of the low-dielectric layer 24, the low-dielectric layer 24 is solidified at a temperature of 200° C. by soft baking. Following this, referring to FIG. 2B, photoresist patterns 25 are formed on the low-dielectric layer 24 by a known photolithography process. The width “W1”, of the photoresist patterns 25 is equal to the exposure limit on the low-dielectric layer 24 by an existing exposure system, and may be in the range of 0.12-0.13 μm.

As shown in FIG. 2C, after the photoresist patterns 25 are formed, the low-dielectric layer 24 is dry etched without the application of a bias voltage and using the patterns 25 as a mask.

Following the dry etching process, the photoresist pattern 25 is stripped, and the low-dielectric pattern (not shown) is cured at a temperature of 400-500° C., as shown in FIG. 2D. As a result, the low-dielectric pattern shrinks to a width “W2”, which is smaller than the width “W1” of the photoresist patterns 25. As a result, the feature size can be reduced to less than 0.1 pm. Although, in the present embodiment, the curing process is performed after the removal of the photoresist pattern 25, the removal of the photoresist patterns and the curing process may be performed at the same time. Alternatively, after the removal of the photoresist patterns 25, the low-dielectric pattern may be cured at a temperature of 400-500° C. and subjected to a cleaning process. In FIG. 2D, reference numeral 24a denotes the shrunken low-dielectric pattern.

Referring to FIG. 2E, the conductive layer 23 for gate electrodes, and the gate insulation layer 24 are patterned in sequence using the shrunken low-dielectric pattern 24a as a mask, thereby resulting in a fine gate electrode “G”.

The present invention may be varied in many different forms and should not be construed as being limited to the embodiments described above. For example, although a single low-dielectric layer is used as a hard mask layer in the present embodiment, the hard mask layer can be formed as a multiple layer for finer patterns. In addition, although the present embodiment is described with reference to gate electrodes, the inventive method can be applied to any pattern with fine feature size.

As previously mentioned, according to the present invention, a hard mask layer is formed of a low-dielectric layer that is shrinkable in width and depth by a thermal process. The low-dielectric layer is patterned using a photoresist pattern with the width equal to the exposure limit by an existing exposure system, and then shrunken by a thermal process. The shrunken low-dielectric pattern is used as a mask in etching the underlying layers, so that the feature size can be reduced beyond the exposure limit of an existing exposure system.

While this invention has been particularly shown and described with reference to preferred embodiments thereof, it will be understood by those skilled in the art that various changes in form and details may be made to the described embodiments without departing from the spirit and scope of the invention as defined by the appended claims.

What is claimed is:

1. A method for forming gate electrodes of a semiconductor device, the method comprising:
forming a gate insulation layer over a semiconductor wafer;
forming a conductive layer over the gate insulation layer;
forming a low-dielectric layer over the conductive layer;
forming a photoresist pattern whose width is equal to the exposure limit on the low-dielectric layer;
patterning the low-dielectric layer using the photoresist pattern as a mask;
removing the photoresist pattern;
shrinking the low-dielectric pattern; and
forming gate electrodes by patterning the conductive layer and the gate insulation layer using the shrunken low-dielectric pattern as a mask.

2. The method of claim 1, wherein the low-dielectric layer is formed of an organic spin-on-glass layer or inorganic spin-on-glass layer.

3. The method of claim 1 or 2, wherein forming the low-dielectric layer comprises:
depositing a low-dielectric layer over the conductive layer for the gate electrodes; and
soft-baking the low-dielectric layer at a predetermined temperature.

4. The method of claim 1, wherein shrinking the low-dielectric pattern includes curing the low-dielectric pattern at a temperature of 400-500° C.

5. The method of claim 1, wherein removing the photoresist pattern and shrinking the low-dielectric pattern are performed at the same time.

6. A method for forming fine patterns of a semiconductor device, the method comprising:
forming a material layer over a semiconductor wafer;
forming a low-dielectric layer over the material layer;
forming a photoresist pattern whose width is equal to the exposure limit on the low-dielectric layer;
patterning the low-dielectric layer using the photoresist pattern as a mask;
removing the photoresist pattern;
shrinking the low-dielectric pattern; and
forming the fine patterns by patterning the material layer using the shrunken low-dielectric pattern as a mask.

7. The method of claim 6, wherein the low-dielectric layer is formed of an organic spin-on-glass layer or inorganic spin-on-glass layer.

8. The method of claim 6 or 7, wherein forming the low-dielectric layer comprises:
depositing a low-dielectric layer over the material layer for the fine patterns; and
soft-baking the low-dielectric layer at a predetermined temperature.

9. The method of claim 6, wherein shrinking the low-dielectric pattern further includes curing the low-dielectric pattern at a temperature of 400-500° C.

10. The method of claim 9, wherein removing the photoresist pattern and shrinking the low-dielectric pattern are performed at the same time.
